(19) United States
(12) Patent Application Publication
(10) Pub. No.: US 2017/0103718 A1
(43) Pub. Date: Apr. 13, 2017

(54) COMPOSITING DISPLAY

(71) Applicant: Adobe Systems Incorporated, San Jose, CA (US)

(72) Inventor: Gavin S.P. Miller, Los Altos, CA (US)

(73) Assignee: Adobe Systems Incorporated, San Jose, CA (US)

(21) Appl. No.: 15/384,783

(22) Filed: Dec. 20, 2016

Related U.S. Application Data
(62) Division of application No. 14/079,942, filed on Nov. 14, 2013.
(60) Provisional application No. 61/755,176, filed on Jan. 22, 2013.

(51) Int. Cl. G09G 3/36; H01L 27/32; G09G 5/10; G09G 3/20; G02F 1/1333; G09G 3/3225

(52) U.S. Cl. CPC G09G 3/3607; G02F 1/13338; G09G 3/3225; G09G 5/10; G09G 3/2003; H01L 27/3232; G02F 2001/133342; G02F 2201/44

(57) ABSTRACT

A device is disclosed that is capable of independently modulating the transparency and emissive color of individual pixels that comprise an electronic display. Modulating the transparency of a transmissive layer allows a darkened or semi-darkened foreground field to be provided on the display. Modulating the color of an emissive layer further makes controllable the brightness and color of the foreground field. When these parameters are controlled, the display can generate partially transparent or opaque graphical elements that appear over the scene behind the display. In some embodiments separate emissive layers are provided on the front and back side of a central transmissive layer, thereby allowing different graphical information to be provided on the front and back side of the display. In other embodiments multiple transmissive and emissive layers can be stacked together, thereby allowing three-dimensional imagery to be generated without the need for viewers to use specialized viewing glasses.

### REFERENCE TO PRIOR APPLICATION

This application is a divisional of U.S. patent application Ser. No. 14/079,942 (filed 14 Nov. 2013), which claims the benefit of U.S. Provisional Patent Application 61/755,176 (filed 22 Jan. 2013). The entire disclosure of both of these priority applications is hereby incorporated by reference herein.

### FIELD OF THE DISCLOSURE

This disclosure relates generally to electronic display devices, and more particularly, to electronic display devices capable of modulating transparency and emissive color of pixels that comprise the display.

### BACKGROUND

As electronic devices have become increasingly commonplace, a wide variety of display technologies have been developed to facilitate user interaction with such devices. Such developments have ranged from early cathode ray vacuum tubes to modern flat panels using liquid crystals or other semiconductive materials. These display technologies have also been integrated with touch sensing technologies, thereby resulting in the development of touchscreens which allow users to directly interact with displayed content.

### BRIEF DESCRIPTION OF THE DRAWINGS

FIG. 1 is a schematic illustration of selected components of a one-sided transparent electronic display device configured in accordance with an embodiment of the present invention.

FIG. 2A is a schematic illustration of selected components of a two-sided transparent electronic display device configured in accordance with an embodiment of the present invention.

FIG. 2B is a schematic cross-sectional illustration of selected components of a two-sided transparent electronic display device configured in accordance with an embodiment of the present invention.

FIG. 3 is a schematic illustration of selected components of a transparent electronic display device configured in accordance with an embodiment of the present invention, wherein the display device is capable of producing an image having a three-dimensional appearance.

FIG. 4 is a schematic illustration of selected components of a transparent electronic display device configured in accordance with an alternative embodiment of the present invention.

FIG. 5A is a schematic illustration of selected components of a two-sided transparent electronic display device that includes a transparent slide having a preprinted graphical element impressed thereon, as configured in accordance with an embodiment of the present invention.

FIG. 5B is a schematic illustration of the appearance of the display device of FIG. 5A as viewed from a first viewing perspective.

FIG. 5C is a schematic illustration of the appearance of the display device of FIG. 5A as viewed from a second viewing perspective that is opposite the first viewing perspective.

### DETAILED DESCRIPTION

A device is disclosed that is capable of independently modulating transparency and emissive color of individual pixels that comprise an electronic display. Modulating the transparency of a transmissive layer allows the background seen through the transparent display to be attenuated and thus allows a darkened or semi-darkened foreground field to be provided on the display. Modulating the color of an emissive layer further allows the brightness and color of the foreground field to be controlled. When these parameters are independently controlled, the display is capable of generating partially transparent or opaque graphical elements that appear over the scene behind the display. In some embodiments separate emissive layers are provided on the front and back side of a central transmissive layer, thereby allowing different graphical information to be provided on the front and back side of the display. In other embodiments multiple transmissive and emissive layers can be stacked together, thereby allowing three-dimensional imagery to be generated without the need for viewers to use specialized viewing glasses. In still other embodiments the display can be provided with one or more touch-sensitive surfaces, thereby allowing users to interact with content displayed on the device surface or surfaces. Numerous other configurations and variations of such display devices will be apparent in light of the foregoing disclosure.

### General Overview

A wide range of technologies can be used to display content on an electronic display device. One example of such technology is a liquid crystal display (LCD), which uses liquid crystals to modulate an external light source, such as light from a backlight, ambient light passing through an otherwise transparent display, or ambient light reflected from an internal mirror. An LCD can be implemented using electrodes made of a transparent material, such as indium tin oxide, thus facilitating use in transparent display applications. A transparent LCD operates by modulating the transparency of individual pixels to control the amount of ambient light reaching the viewer's eye. However, because an LCD requires an external light source, a transparent display using LCD technology generally requires a bright background behind the display. Such devices can work well if the background is bright, but they are incapable of producing bright colors that are opaque with respect to the scene behind the display. LCD display technology also often provides unsatisfactory results when used without a bright background.

Thus, and in accordance with an embodiment of the present invention, compositing display devices are provided herein that modulate both the transparency and emissive color of the individual pixels that comprise the display. In particular, devices are provided that include a first component capable of modulating the transparency of the pixels and a second component capable of modulating the emissive color of the pixels. For example, in certain embodiments the first component may comprise a greyscale liquid crystal element, a red-green-blue (RGB) liquid crystal element, another combination of colored filters, or any other suitable element capable of modulating the amount of light passing through the element. This first component attenuates background light and provides background opacity. In such embodiments, the second component may comprise an organic light emitting diode (OLED), a light-emitting electrochemical cell (LEC), or any other suitable element capable of emitting light at a selectable wavelength and intensity. An OLED, for example, uses organic molecules that emit light when subjected to an electric current, and is therefore capable of providing bright colors that appear over a background scene. Thus, when these emissive and transmissive components are used together, it is possible to provide a transparent compositing display that is capable of producing brightly colored elements over an opaque or partially opaque background. The ability to modulate both transparency and emitted color provides a device with substantially improved image quality under a wide variety of operating conditions.

As will be appreciated in light of this disclosure, the various embodiments of the display devices disclosed herein can be controlled using one or more drivers capable of synchronously varying the transmittance of the pixels that comprise the first component and the emissivity of the pixels that comprise the second component. The one or more drivers can be integrated into the display device or can be provided separately, and can employ any suitable pixel addressing scheme such as active matrix addressing or passive matrix addressing. It will be appreciated that the present invention is not limited to any particular configuration of the driver or drivers which are used to control the components for modulating the transmittance and emissive color of the pixels.

### Example Device Configurations

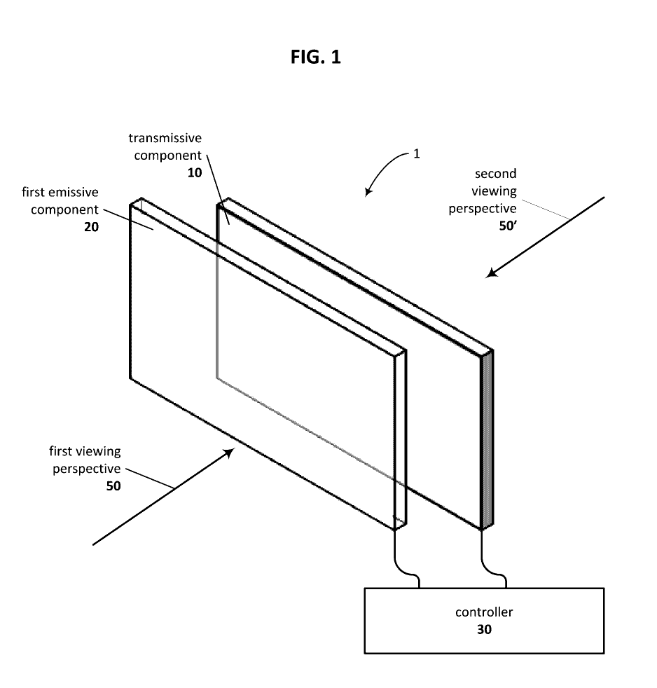

FIG. 1 schematically illustrates selected components of an example embodiment of a one-sided transparent compositing display device 1 that is capable of modulating both the transparency and emissive color of the pixels that comprise the display. The compositing display device 1 includes a transmissive component 10 that is capable of modulating the intensity of light passing therethrough, and a first emissive component 20 that is capable of modulating the wavelength and intensity of light emitted therefrom. The components 10, 20 are positioned adjacent to each other, such that light from an external source can propagate through the transmissive component 10, through the first emissive component 20, and to a viewer looking at the display device 1 from a first viewing perspective 50. Light emitted by the first emissive component 20 can also propagate directly to a viewer having the first viewing perspective 50. If the device 1 is viewed from a second viewing perspective 50′ that is opposite the first viewing perspective 50, the color of a selected pixel can be modulated by the transparency of a corresponding element of the transmissive component 10. In opaque regions where the transmissive component 10 allows little or no light to propagate, the emissive color generated by the first emissive component 20 would be nearly or completely obscured, as viewed from the second viewing perspective 50′.

As described above, the components 10, 20 can be fabricated using transparent electrodes, thereby providing the device 1 with a substantially transparent appearance when no image is displayed thereon. Although the components 10, 20 are illustrated as being spaced apart from each other for purposes of clarity in FIG. 1, it will be recognized that they can also be placed in direct contact with each other, laminated together, or otherwise formed into a unitary display device 1. For example, in one embodiment OLED elements that comprise the first emissive component 20 can be printed directly onto the surface of an LCD screen that comprises the transmissive component 10. Furthermore, while the components 10, 20 of the example display device 1 are illustrated as having a rectangular shape, it will be recognized that other physical shapes and sizes can be used in other embodiments, and that the present invention is not limited to a display device or components having a particular shape or size.

In certain embodiments the transmissive component 10 comprises a greyscale LCD that is capable of modulating the intensity of light passing therethrough. In alternative embodiments the transmissive component 10 comprises a RGB LCD that is capable of modulating both the wavelength and intensity of light passing therethrough. In applications where a bright background is frequently available, improved image quality can be achieved by using an RGB LCD as the transmissive component 10. However, in other applications using a greyscale LCD can advantageously increase the amount of light transmitted through the transmissive component 10, and thereby produce a brighter image on the display device 1; in such embodiments the color in the resulting image is provided by the first emissive component 20. In still other embodiments, other technologies can be used to modulate the intensity of the light transmitted through the transmissive component 10, and optionally, the wavelength of the transmitted light. Thus it will be recognized that the present invention is not intended to be limited to a particular type of device that provides the function of transmissive component 10.

As disclosed previously, the first emissive component 20 is any suitable component capable of emitting light at a selectable wavelength and frequency. In certain embodiments the first emissive component 20 comprises an OLED, which has the advantage of being relatively lightweight, providing relatively wide viewing angles, and having a relatively fast response time. However, while use of an OLED as the first emissive component 20 provides certain advantages, it will be recognized that other emissive elements can be used in other embodiments, and that the present invention is not intended to be limited to a particular type of emissive device that provides the function of first emissive component 20.

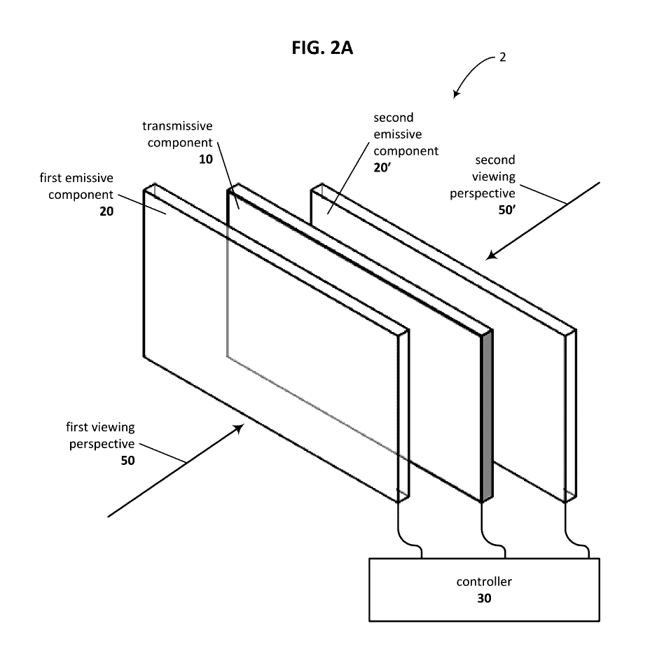

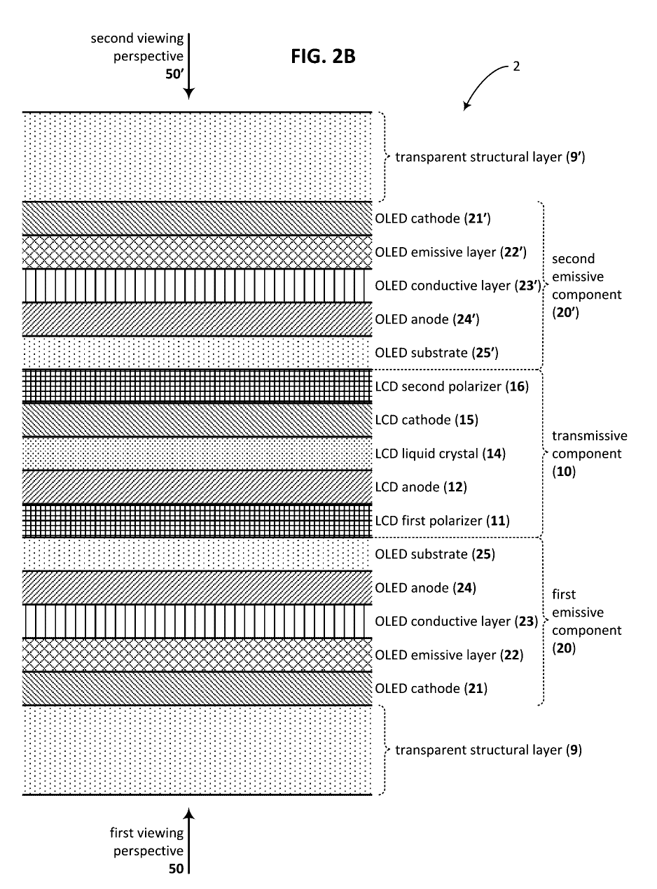

FIG. 2A schematically illustrates selected components of an example embodiment of a two-sided transparent compositing display device 2 that is capable of modulating both the transparency and emissive color of the pixels that comprise the display. The bidirectional compositing display device 2 includes a transmissive component 10 and first emissive component 20 which can be configured, for example, as described above with respect to the one-sided device 1 illustrated in FIG. 1. The compositing display device 2 further includes a second emissive component 20′ positioned on an opposite side of the transmissive component 10 with respect to the first emissive component 20. Thus the transmissive component 10 is positioned between the first and second emissive components 20, 20′. Although these various components are illustrated as being spaced apart from each other for purposes of clarity in FIG. 2A, it will be recognized that they can also be placed in direct contact with each other, laminated together, or otherwise formed into a unitary display device 2. For example, in one embodiment OLED elements that comprise the first and second emissive components 20, 20′ are printed directly onto the opposing surfaces of an LCD screen that comprises the transmissive component 10. The second emissive component 20′ can use an identical, similar or different technology for emitting light as the first emissive component 20.

The two-sided display device 2 is configured for viewing from both the first viewing perspective 50, as well as an oppositely-oriented second viewing perspective 50′. Such a two-sided display device 2 has a transparency that is the same from both the first and second viewing perspectives 50, 50′, but an emissive color that may be different on opposite sides of the display. This advantageously allows different graphical elements to be displayed to different viewers at the opposing viewing perspectives 50, 50′. In addition, in such embodiments the transmissive component 10 can be used to prevent emissions from a selected emissive component from reaching a viewer positioned on the opposite side of the transmissive component 10 with respect to that selected emissive component. This could be used, for example, to prevent a viewer at the first viewing perspective 50 from seeing light emitted by the second emissive component 20′.

FIG. 2B is a schematic cross-sectional illustration of selected subcomponents that comprise transmissive component 10 and first and second emissive components 20, 20′ of two-sided display device 2. These subcomponents may be packaged between transparent structural layers 9, 9′ which are configured to protect and provide structural support for device 2. As illustrated, in certain embodiments transmissive component 10 comprises a liquid crystal layer 14 that is positioned between an anode 12 and a cathode 15 as well as first and second polarizers 11, 16. Liquid crystal layer 14 may comprise any suitable material that can controllably modulate the polarization of light passing therethrough in response to an electric field applied between anode 12 and cathode 15. Polarizers 11, 16 are crossed with respect to each other, such that transmissive component 10 can be made substantially transparent by applying an electric field between anode 12 and cathode 15. Anode 12 and cathode 15 may comprise any suitable transparent or substantially transparent conductive material, such as indium tin oxide, and may be connected to controller 30 using connectors which are not illustrated in FIG. 2B for purposes of clarity. In general, it will be appreciated that other configurations and technologies may be used to provide transmissive component 10, and thus that the present invention is not intended to be limited to any particular configuration or technology. For example, polarizers 11, 16 may comprise linear or circular polarizing filters which have crossed polarizations with respect to each other.

Still referring to FIG. 2B, each of first and second emissive components 20, 20′ are illustrated as comprising an emissive layer 22, 22′ and a conductive layer 23, 23′, both of which are positioned between an anode 24, 24′ and a cathode 21, 21′. Emissive layers 22, 22′ and conductive layers 23, 23′ comprise organic molecules or polymers. Anode 24, 24′ comprises a transparent conductive material that removes electrons from the organic/polymeric layers when a current flows through the device. Likewise cathode 21, 21′ comprises a transparent conductive material that injects electronics into the organic/polymeric layers when a current flows through the device. Anode 24, 24′ and cathode 21, 21′ may be connected to controller 30 using connectors which are not illustrated in FIG. 2B for purposes of clarity. Conductive layer 23, 23′ transports holes from anode 24, 24′, while emissive layer 22, 22′ transports electrons from cathode 21, 21′. Electrostatic forces bring the electrons and the holes towards each other and they recombine in emissive layer 22, 22′ to form an exciton, a bound state of the electron and hole. The decay of this excited state results in a relaxation of the energy levels of the electron, accompanied by emission of radiation whose frequency is in the visible region. The frequency of this radiation depends on the band gap of the material comprising emissive layer 22, 22′. First and second emissive components 20, 20′ optionally include a transparent substrate 25, 25′ that provides additional structural support for device 2, although it will be appreciated that in alternative embodiments substrate 25, 25′ may be omitted and the subcomponents of emissive components 20, 20′ may be formed directly on the adjacent polarizers 11, 16 of transmissive component 10. In general, it will be appreciated that other configurations and technologies may be used to provide emissive components 20, 20′, and thus that the present invention is not intended to be limited to any particular configuration or technology in this regard.

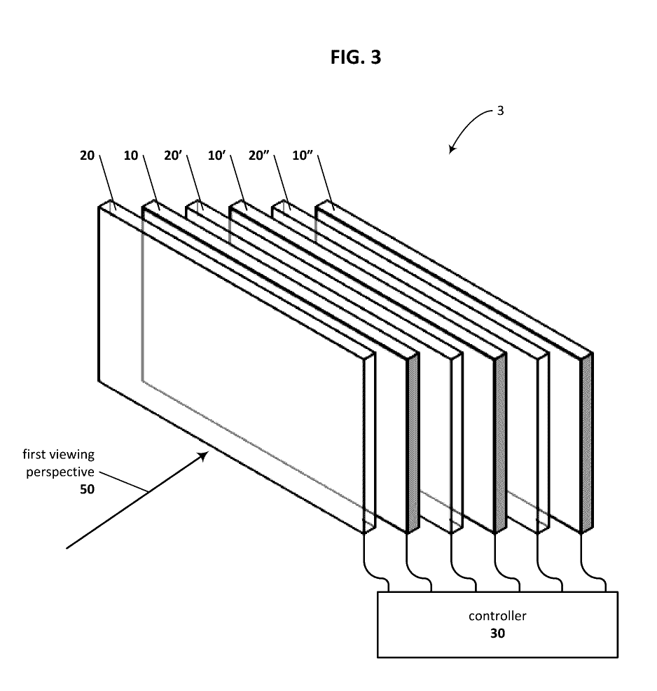

FIG. 3 schematically illustrates selected components of an example embodiment of a three-dimensional transparent compositing display device 3 that is capable of modulating both the transparency and emissive color of the pixels that comprise the display. The three-dimensional display device 3 includes a plurality of transmissive components 10, 10′, 10″ which are stacked in an alternating fashion with a plurality of emissive components 20, 20′, 20″. These components can be configured, for example, as described above with respect to the one-sided device 1 illustrated in FIG. 1. For example, in one embodiment each of the transmissive components 10, 10′, 10″ comprise a greyscale LCD and each of the emissive components 20, 20′, 20″ comprise an array of OLED elements. While three pairs of transmissive and emissive components are illustrated in FIG. 3, it will be appreciated that more or fewer pairs can be provided in other embodiments. And although the various components are illustrated as being spaced apart from each other in FIG. 3, it will be recognized that they can alternatively be placed in direct contact with each other, laminated together, or otherwise formed into a unitary display device 3.

By generating slightly different images at slightly different distances from the first viewing perspective 50, the display device 3 can be used to create the appearance of three-dimensional images embedded in a volume. Each of the different images can be provided at a particular depth in the display, and can be defined by a unique spatially varying emissive color and opacity map. Three-dimensional imagery generated using such a device would have enhanced fidelity with respect to conventional three-dimensional imaging techniques, and could be appreciated without the need for the viewer to wear the specialized glasses which are generally necessary in conventional systems. In particular, three-dimensional imagery generated in this way would maintain correct correspondence between the viewer's eye convergence angle and the view's focus, which cannot be maintained using conventional flat-panel display technology for rendering three-dimensional imagery. Displays using such a configuration are particularly useful for layer-based imaging and/or design systems.

Layering a plurality of one-sided transparent compositing display elements, as illustrated in FIG. 3, can enable a single-sided three-dimensional display; in a modified embodiment a plurality of two-sided transparent compositing display elements are layered to provide a double-sided three-dimensional display. This could be accomplished, for example, by adding an additional emissive component on the exterior side of the display adjacent to transmissive component 10″.

Implementing multiple pairs of transmissive and emissive elements can also improve visual fidelity and reduce visual artifacts present in a tensor display. A tensor display is a compressive light field display that uses a plurality of time-multiplexed transmissive elements that are illuminated by directional or uniform backlighting. A three-dimensional or four-dimensional array of images—referred to as a light field—is used to capture the appearance of a scene. The transparency at each layer of the display is optimized so as to best approximate the target light field, based on the competing demands of viewing the display from the different directions which correspond to the individual images comprising the light field. Using a plurality of transmissive elements illuminated by a backlight causes the color of a given pixel to be tied to the brightness of that pixel, thus resulting in reduced visual fidelity. By providing each layer with the ability to independently modulate both the emissive color and the transparency of the individual pixels, such as disclosed herein, the resulting tensor display can better approximate the appearance of the target light field. Thus in one embodiment compositing display device 3 comprises forms part of a tensor display capable of generating a compressive light field that represents a multi-dimensional array of images.

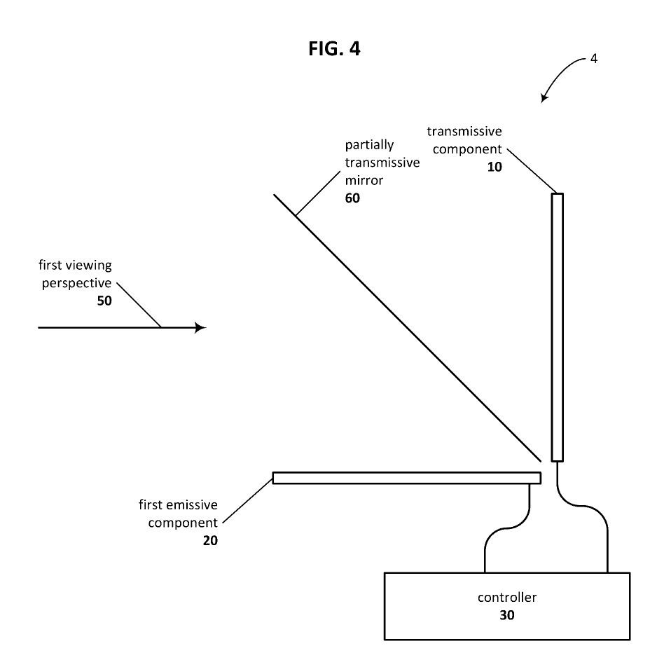

FIG. 4 schematically illustrates selected components of an alternative embodiment of a one-sided transparent compositing display device 4 that is capable of modulating both the transparency and emissive color of the pixels that comprise the display. The compositing display device 4 includes a transmissive component 10 and a first emissive component 20 that are separated by a partially transmissive mirror 60. The transmissive component 10 and the first emissive component 20 can be configured, for example, as described above with respect to the composite transparent display device illustrated in FIG. 1. For example, in one embodiment of the compositing display device 4, the transmissive component 10 comprises a greyscale LCD and the first emissive component 20 comprises an OLED array. The partially transmissive mirror 60 can be any suitable mirror capable of partially reflecting and partially transmitting a portion of the light incident thereon. Furthermore, while the transmissive and emissive components 10, 20 are illustrated in FIG. 4 as being positioned at a 90° angle with respect to each other, it will be appreciated that other physical arrangements of the components 10, 20 and the mirror 60 can be used in other embodiments.

In such embodiments externally generated light, such as ambient light propagates through the transmissive component 10, at which point its intensity can be modulated. The light passes through the partially transmissive mirror 60 and reaches a viewer at the first viewing perspective 50. Light emitted by the first emissive component 60 reflects from the partially transmissive mirror 60 and also reaches the viewer. As with the embodiment illustrated in FIG. 1, this configuration is also capable of producing brightly colored elements over an opaque or partially opaque background. Such embodiments provide the additional advantage of being easy to fabricate at a low cost, and may be appropriate for applications where a compact or flat physical configuration is less important. For example, the example embodiment illustrated in FIG. 4 can be implemented using an emissive component 20 that is opaque.

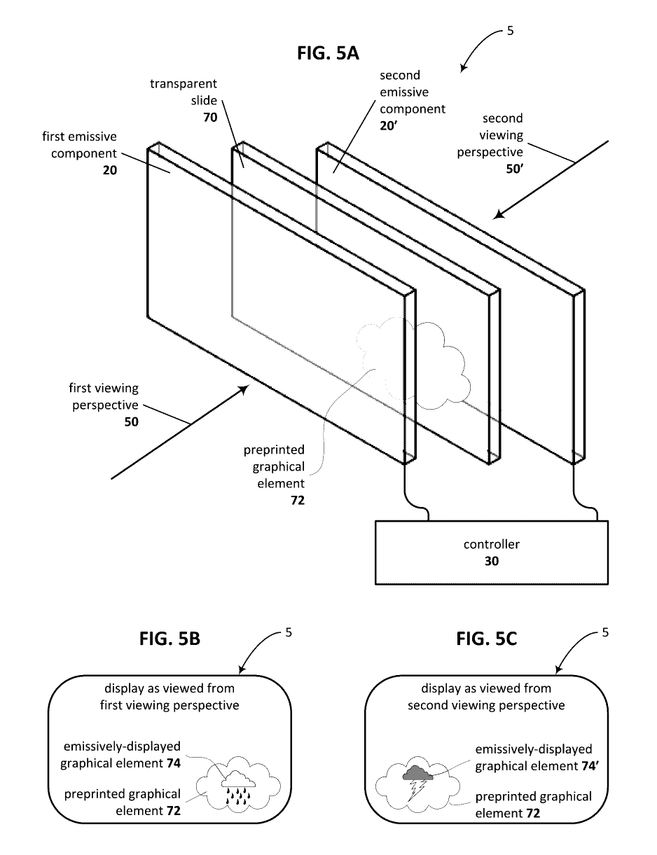

FIG. 5A schematically illustrates selected components of a two-sided transparent electronic display device 5 that includes a transparent slide 70 having a preprinted graphical element 72 impressed thereon. In such embodiments, transparent slide 70 may comprise a passive component that is substantially transparent and that includes one or more preprinted graphical elements 72 visible thereon. Preprinted graphical element 72 may correspond to a fixed feature of display 5 that is not intended to change, such as a region that is permanently opaque or semi-transparent. For example, FIG. 5B illustrates the appearance of display device 5 as viewed from first viewing perspective 50, which FIG. 5C illustrates the appearance of display device 5 as viewed from second viewing perspective 50′. Preprinted graphical element 72 is visible from both perspectives, although it is positioned differently and appears as a mirror image because perspectives 50, 50′ are opposing. However, first emissive component 20 can be used to generate a first emissively-generated graphical element 74 that is visible only from first viewing perspective 50. Likewise, second emissive component 20′ can be used to generate a second emissively-generated graphical element 74′ that is visible only from second viewing perspective 50′.

Use of transparent slide 70 to define fixed opaque or semi-transparent regions of the display enables transmissive component 10 to be omitted from device 5. Where transmissive component 10 is incapable of achieving 100% transmission of light, replacing this component with transparent slide 70 that is capable of achieving nearly 100% transmission of light enables device 5 to have an overall higher degree of transparency. It also reduces the manufacturing costs, thickness and weight associated with device 5. While FIG. 5A illustrates a two-sided transparent display device 5 including a preprinted transparent slide 70, it will be appreciated that in other embodiments an equivalent or similar preprinted transparent slide 70 may be incorporated into, for example, a one-sided display device (such as illustrated in FIG. 1), a three-dimensional display device (such as illustrated in FIG. 3), or alternative embodiments (such as illustrated in FIG. 4).

The compositing devices disclosed herein are optionally provided with one or more touch-sensitive surfaces. The one or more touch-sensitive surfaces can be implemented using any of a variety of technologies for detecting contact, such as a transparent resistive touchscreen panel or a transparent capacitive touchscreen panel. The touch-sensitive surface can be applied to a front side of the display, a rear side of the display, or both sides of the display. Providing a touch-sensitive surface on a surface opposite that which a user views the device advantageously reduces the extent to which the implement used to interact with the touch-sensitive surface, such as a finger or stylus, blocks the user's view of the display. Thus a user can, for example, drag and drop an icon shown on the display while still being able to view the full display contents.

In certain embodiments the compositing display devices disclosed herein are optionally provided with a diffusion filter positioned on one side of the device, thereby causing remote objects in the background field to appear out of focus, while foreground objects would be increasingly in focus. The diffusion filter could be implemented using a fixed optical element, a uniform cell that could have its optical scattering properties be adjusted globally, or an array of pixels each of which could have their scattering properties individually controllable. However, regardless of the particular implementation, using a diffuser would advantageously reduce distraction caused by background clutter, and would be particularly useful when applied in conjunction with a touch-sensitive surface applied to the same side of the display as the diffusion filter, as this would allow the pointing device used with the touch-sensitive surface to remain in focus. The device or a region of the device could be configured to have the appearance of frosted glass, which is a desirable appearance frequently used in signage and glass display applications.

A wide variety of other optical components can be included in or integrated into the compositing display devices disclosed herein. For example, including a layer that controls the diffusion of light transmitted through or emitted by an optical component of the display could be used to provide the display with a frosted glass effect. As another example, a directional filter could be used to reduce the viewing angle for one or both sides of the display, which may be desirable for privacy purposes. As yet another example, an anti-reflective coating could be used to reduce glare from the viewable surface or surfaces. Additional or alternative optical components can be used in other embodiments, and it will be recognized that the present invention is not intended to be limited to a particular component or set of components which are used with the transparent compositing display device. For example, in certain embodiments one or more of the transmissive and emissive components are provided on a curved or flexible surface, thereby enabling the display device to be non-planar.

In certain embodiments transmissive component 10 comprises a spatially segmented LCD or photochromic display, thereby allowing certain regions of the display to be modulated in transparency, such that one or more arbitrarily-shaped regions can be controlled independently or provided with a fixed transparency parameter. Segmented displays may have a reduced manufacturing cost as compared to a full array of individually addressable pixels. In other embodiments transmissive component 10 comprises a single element whose transparency may be modified uniformly across the entire component. This would allow the resulting display to have a “privacy mode” that, when activated, would cause the display to no longer be transparent. Such a privacy mode could also be used to compensate for the brightness of the background scene in a controlled way, as well as reduce manufacturing costs by eliminating the need to provide individually addressable pixels.

As illustrated, the display devices disclosed herein optionally include a driver or controller 30 capable of synchronously varying the transmittance of the pixels that comprise the one or more transmissive components and the emissivity of the pixels that comprise the one or more emissive components. In embodiments wherein an RGB LCD is used as a transmissive component, the controller 30 can also be configured to modulate the wavelength of the light transmitted through the RGB LCD. The controller 30 can be integrated into the display device or can be provided separately, and can employ any suitable pixel addressing scheme such as active matrix addressing or passive matrix addressing.

### Application

The various embodiments of the compositing display devices disclosed herein can be implemented in a variety of different applications. For example, in certain embodiments such a device can be configured as a standalone display device that can be coupled to another device that is used to control the display, such as a desktop computer. In other embodiments a compositing display can be connected to a device that is used to convert an external signal source into content that is to be displayed, such as in the case of a set-top box that is configured for use with a cable or satellite television system. In still other embodiments a compositing display can be integrated into an electronic device such a mobile phone, a tablet computer or a laptop computer. The various embodiments disclosed herein can also be used for other transparent display applications such as heads-up displays, augmented reality systems, product display boxes and even windows. For example, in one embodiment isolated video sprites can be displayed on an otherwise transparent window for entertainment purposes. Thus it will be appreciated that the example embodiments disclosed herein can be used in a wide variety of applications, and that the present invention is not intended to be limited to any particular use, application or implementation.

The display devices disclosed herein can also be used to produce a wide variety of different visual effects which can be useful in certain applications. For example, the appearance of an opaque piece of white paper positioned on a piece of transparent glass can be achieved by using the transmissive component to reduce or eliminate light transmission in a selected region and using the emissive component to generate white light having the appearance of the piece of paper in that region. In this case the emissive component can also be used to generate the appearance of images having arbitrary color on the piece of paper. The appearance of a transparent hole in the piece of paper can be achieved by causing the transmissive component to pass light in the region of the hole and causing the emissive component to not emit light in that region. Using a fractional transparency allows anti-aliased edges and semi-transparent regions to be generated. The compositing display devices disclosed herein can produce higher quality images than a conventional OLED-based transparent display, which is only capable of adding light to that which is already transmitted through the display, and which therefore has difficulty generating opaque regions, especially where a bright background is present.

As another example, the two-sided display 2 illustrated in FIGS. 2A and 2B can be used to display different graphical elements to viewers at the two opposing viewing perspectives 50, 50′ while still allowing both viewers to see the same transparent or partially-transparent regions of the display. This allows, for example, the display of an opaque piece of paper having arbitrary color, wherein different information is provided on opposite sides of the paper. For instance, forward-oriented text could be displayed to a first viewer at the first viewing perspective 50, while reversed-oriented text or different forward-oriented text is simultaneously displayed to a second viewer at the second viewing perspective 50′. In such applications, the transmissive component 10 can optionally be used to prevent emissions from a selected emissive component from reaching a viewer positioned on the opposite side of the transmissive component 10. This would allow a graphical element displayed to a user on one side of the display 2 to be hidden from a second user on the opposite side of the display 2. Such effects could not be accomplished using a conventional transparent display that relies only on adding light generated by an emissive component to background light already passing through the transparent display.

Other applications for the two-sided display include a double-sided display for an office window, wherein the status of an occupant is provided on a label displayed on an exterior side of the window, while reminders or other personalized information is provided on the interior side of the displayed label. Or such a display could also be integrated into a kiosk that could be placed between two people interacting with each other, such as a salesperson and a customer, or a teacher and a student. The visual assets presented on such a two-sided display could be controlled by one person and consumed by the other, while the transparent nature of the display would still allow the two people to maintain eye contact with each other during their interaction.

### Conclusion

Numerous variations and configurations will be apparent in light of this disclosure. For instance, one example embodiment provides a display device that comprises a first array of pixels configured to modulate an intensity of light that is propagated therethrough in response to a first control signal. The display device further comprises a second array of pixels that is positioned adjacent to the first array of pixels. The pixels comprising the second array are configured to emit light at a selected wavelength and intensity in response to a second control signal. In some cases, the pixels comprising the first array are liquid crystal elements. In some cases, the pixels comprising the first array are greyscale liquid crystal elements. In some cases, the pixels comprising the second array are substantially transparent to ambient light. In some cases, the pixels comprising the second array are organic light emitting diode elements. In some cases, the display device further comprises a controller configured to provide the first control signal so as to control the intensity of light propagated through the first array. In some cases, the display device further comprises a controller configured to provide the second control signal so as to control the selected wavelength and intensity of light emitted from the pixels comprising the second array. In some cases, the display device further comprises a third array of pixels that is positioned such that the first array is between the second and third arrays, wherein the pixels comprising the third array are configured to emit light at an alternative selected wavelength and intensity. In some cases, the display device further comprises a touch-sensitive surface positioned on the first array of pixels. In some cases, the display device further comprises a first touch-sensitive surface positioned on the first array of pixels, and a second touch-sensitive surface positioned on the second array of pixels.

Another example embodiment of the present invention provides a display device that comprises a transmissive component including a plurality of liquid crystal elements. The display device further comprises a transparent emissive component that is positioned adjacent to the transmissive component and that includes a plurality of light emitting elements. Light passing through a selected one of the liquid crystal elements is composited with light emitted from a corresponding selected one of the light emitting elements. In some cases, the display device further comprises (a) a plurality of transmissive components, each of which includes a plurality of liquid crystal elements; and (b) a plurality of transparent emissive components, each of which includes a plurality of light emitting elements, wherein the transmissive and emissive components are layered in an alternating fashion. In some cases, the display device further comprises a second transparent emissive component that is positioned such that the transmissive component is positioned between the first and second transparent emissive components, wherein the second transparent emissive component is configured to emit light at a selected wavelength and frequency. In some cases, the liquid crystal elements comprising the transmissive component are selected from the group consisting of greyscale liquid crystal elements and red-green-blue liquid crystal elements.

Another example embodiment of the present invention, provides a method for displaying an image. The method comprises transmitting a modulated portion of light through a first array of pixels. The method further comprises emitting a modulated intensity and wavelength of light from a second array of pixels. The method further comprises compounding light transmitted through the first array of pixels with light emitted from the second array of pixels. In some cases, the second array of pixels is printed on a surface of the first array of pixels. In some cases, transmitting the modulated portion of light through the first array of pixels further comprises modulating a wavelength of light transmitted through the first array. In some cases, the first array of pixels comprises a plurality of liquid crystal display elements, and the second array of pixels comprises a plurality of organic light emitting diode elements. In some cases, at least one of the first array of pixels and/or the second array of pixels comprises a touch-sensitive surface. In some cases, a third array of pixels is positioned such that the first array is positioned between the second and third arrays; in such cases the method further comprises (a) emitting an alternative modulated intensity and wavelength of light from the third array of pixels; and (b) compounding light transmitted through the first array of pixels with light emitted from the third array of pixels.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not be this detailed description, but rather by the claims appended hereto.

What is claimed is:

1. A display device comprising:
a first array of pixels configured to modulate an intensity of light that is propagated therethrough in response to a first control signal;
a second array of pixels that is positioned adjacent to the first array of pixels, wherein the pixels comprising the second array are configured to emit light at a specified wavelength and intensity in response to a second control signal; and
a third array of pixels that is positioned such that the first array is between the second and third arrays, wherein the pixels comprising the third array are configured to emit light at an alternative specified wavelength and intensity.

2. The display device of claim 1, further comprising a diffusion filter positioned on one side of the display device, such that ambient light propagating into a first side of the display device, through the first, second, and third arrays of pixels, and out of a second side of the display device that is opposite the first side, also passes through the diffusion filter.

3. The display device of claim 1, wherein the pixels comprising the third array are configured to emit light at the alternative specified wavelength and intensity in response to a third control signal.

4. The display device of claim 1, wherein the pixels comprising the first array are liquid crystal elements.

5. The display device of claim 1, wherein the pixels comprising the first array are greyscale liquid crystal elements.

6. The display device of claim 1, wherein the pixels comprising the second array are substantially transparent to ambient light.

7. The display device of claim 1, wherein the pixels comprising the second array are organic light emitting diode elements.

8. The display device of claim 1, further comprising a controller configured to provide the first control signal so as to control the intensity of light propagated through the first array.

9. The display device of claim 1, further comprising a controller configured to provide the second control signal so as to control the specified wavelength and intensity of light emitted from the pixels comprising the second array.

10. The display device of claim 1, further comprising touch-sensitive surfaces positioned on each of the second and third arrays of pixels.

11. The display device of claim 1, wherein the first control signal is independent of the second control signal, and the second control signal is independent of the first control signal.

12. A display device comprising:
a plurality of planar transmissive components, each of which includes an array of liquid crystal elements; and
a plurality of planar emissive components, each of which is positioned adjacent to at least one of the planar transmissive components, and each of which includes an array of light emitting elements,
wherein ambient light passing through a particular one of the planar transmissive components is composited with light emitted from a corresponding particular one of the planar emissive components.

13. The display device of claim 12, wherein each of the planar emissive components is substantially transparent to ambient light.

14. The display device of claim 12, wherein:
the particular planar transmissive component is positioned between two planar emissive components; and
wherein each of the two planar emissive components emits light based on corresponding first and second control signals.

15. The display device of claim 12, wherein the liquid crystal elements comprising the particular planar transmissive component are selected from a group consisting of greyscale liquid crystal elements and red-green-blue liquid crystal elements.

16. A method for displaying an image, the method comprising:
transmitting a modulated portion of ambient light through a first array of pixels;
emitting a modulated intensity and wavelength of light from a second array of pixels;
compounding the ambient light transmitted through the first array of pixels with the light emitted from the second array of pixels;
emitting an alternative modulated intensity and wavelength of light from a third array of pixels, wherein the third array of pixels is positioned such that the first array is positioned between the second and third arrays; and
compounding the ambient light transmitted through the first array of pixels with the light emitted from the third array of pixels.

17. The method of claim 16, wherein the second array of pixels is printed on a surface of the first array of pixels.

18. The method of claim 16, wherein transmitting the modulated portion of light through the first array of pixels further comprises modulating a wavelength of light transmitted through the first array.

19. The method of claim 16, wherein the first array of pixels comprises a plurality of liquid crystal display elements, and the second array of pixels comprises a plurality of organic light emitting diode elements.

20. The method of claim 16, wherein the second array of pixels and the third array of pixels each comprises a touch-sensitive surface.
